(19) United States
(12) Patent Application Publication
(10) Pub. No.: US 2018/0338388 A1
(43) Pub. Date: Nov. 22, 2018

(54) COOLING DEVICE, ELECTRONIC APPARATUS, AND COOLING SYSTEM

(71) Applicant: FUJITSU LIMITED, Kawasaki-shi (JP)

(72) Inventors: JIE WEI, Hachioji (JP); Keizou Takemura, Kawasaki (JP); Michimasa AOKI, Kawasaki (JP)

(73) Assignee: FUJITSU LIMITED, Kawasaki-shi (JP)

(21) Appl. No.: 15/970,916

(22) Filed: May 4, 2018

(30) Foreign Application Priority Data
May 16, 2017 (JP) 2017-097030

(51) Int. Cl. H05K 7/20; F28F 13/12; F28C 1/00; F28F 1/00

(52) U.S. Cl. CPC H05K 7/20236; F28F 13/125; F28F 2210/10; F28F 1/00; H05K 7/20272; F28C 1/00

(57) ABSTRACT

A cooling device includes an immersion tank that stores a refrigerant liquid, and a cooling pipe that is disposed on a peripheral wall of the immersion tank, at least a portion of which is exposed from the peripheral wall to an inside of the immersion tank, and through which cooling water flows.

### CROSS-REFERENCE TO RELATED APPLICATION

This application is based upon and claims the benefit of priority of the prior Japanese Patent Application No. 2017-97030, filed on May 16, 2017, the entire contents of which are incorporated herein by reference.

### FIELD

The embodiments discussed herein are related to a cooling device, an electronic apparatus, and a cooling system.

### BACKGROUND

In the related art, there is a cooling system including an immersion tank for storing a refrigerant liquid and a heat radiating portion (for example, reserve tank) through which the refrigerant liquid circulates between the heat radiating portion and the immersion tank. In the cooling system, for example, an electronic device is accommodated in the immersion tank, and the electronic device is cooled by immersing the electronic device in the refrigerant liquid. In addition, the refrigerant liquid that has absorbed heat from the electronic device in the immersion tank is sent to the heat radiating portion through a pipe, and is cooled by the heat radiating portion.

However, as described above, in the cooling system that circulates the refrigerant liquid between the immersion tank and the heat radiating portion, the amount of the refrigerant liquid which is normally considered to be expensive to be used by the amount of the refrigerant liquid sent out of the immersion tank increases, and thus the cost increases. Therefore, in order to suppress the increase in cost, it is desirable to reduce the amount of refrigerant liquid to be used. In addition, in such a cooling system, it is desirable that the electronic device has high cooling capability as an original performance.

The followings are reference documents.

[Document 1] Japanese Laid-open Patent Publication No. 7-243743,

[Document 2] Japanese Laid-open Patent Publication No. 6-323711,

[Document 3] Japanese Laid-open Patent Publication No. 4-372159, and

[Document 4] Japanese Laid-open Patent Publication No. 2009-158803.

### SUMMARY

According to an aspect of the invention, a cooling device includes an immersion tank that stores a refrigerant liquid, and a cooling pipe that is disposed on a peripheral wall of the immersion tank, at least a portion of which is exposed from the peripheral wall to an inside of the immersion tank, and through which cooling water flows.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a conceptual diagram illustrating a cooling system according to an embodiment;

FIG. 2 is a plan sectional view of a cooling device illustrated in FIG. 1;

FIG. 3 is a side sectional view of a cooling device to which a first modification example of a cooling pipe illustrated in FIG. 2 is applied;

FIG. 4 is a plan sectional view of a cooling device to which a second modification example of the cooling pipe illustrated in FIG. 2 is applied; and

FIG. 5 is a plan sectional view of a cooling device to which a third modification example of the cooling pipe illustrated in FIG. 2 is applied.

### DESCRIPTION OF EMBODIMENTS

First, a cooling system S according to an embodiment of the technology disclosed in the present application will be described.

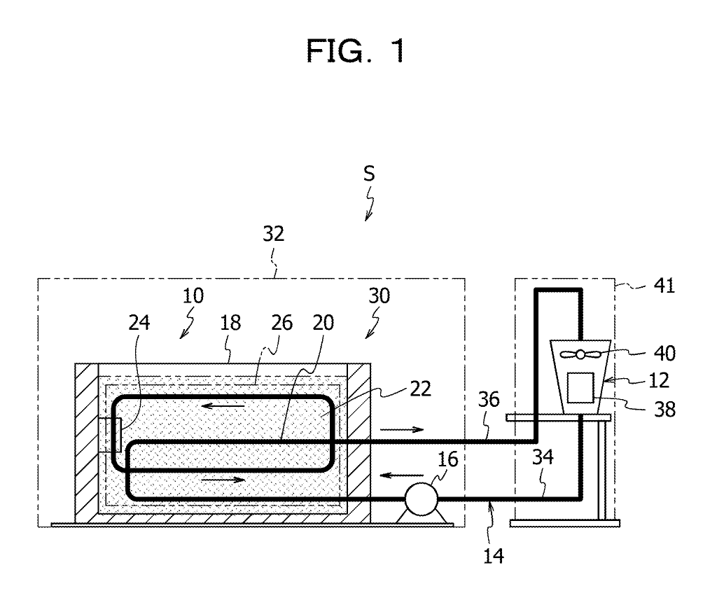

In FIG. 1, a cooling system S according to an embodiment of the technology disclosed in the present application is conceptually illustrated. As illustrated in FIG. 1, the cooling system S according to the present embodiment includes a cooling device 10, a cooling tower 12, a circulation pipe 14, and a circulation pump 16.

The cooling device 10 has an immersion tank 18 and a cooling pipe 20. The immersion tank 18 is formed in an open box shape opening upward. In the immersion tank 18, a refrigerant liquid 22 is stored. In the immersion tank 18, an agitating mechanism 24 is disposed. The agitating mechanism 24 has, for example, a fan, a pump, and the like, and has a function of agitating the refrigerant liquid 22 in the immersion tank 18. In the immersion tank 18, an electronic device 26 including a heating element such as an electronic component that generates heat is accommodated. The electronic device 26 is accommodated in the immersion tank 18 so as to be immersed in the refrigerant liquid 22 and cooled.

The cooling device 10 and the electronic device 26 form an electronic apparatus 30 with a cooling function. The electronic apparatus 30 including the cooling device 10 and the electronic device 26 functions as, for example, a server or the like. The electronic apparatus 30 is disposed in a building 32 such as a container. An inlet portion of the cooling pipe 20 is connected to an outlet portion of the cooling tower 12 via a supply pipe 34, and an outlet portion of the cooling pipe 20 is connected to an inlet portion of the cooling tower 12 via a return pipe 36.

The cooling pipe 20, the supply pipe 34, and the return pipe 36 form the circulation pipe 14 through which a cooling water circulates between the immersion tank 18 and the cooling tower 12. In the circulation pipe 14, the circulation pump 16 is disposed. In the present embodiment, as an example, the circulation pump 16 is disposed in the supply pipe 34 of the circulation pipe 14.

The cooling tower 12 is disposed outside the building 32. The cooling tower 12 has a heat exchanger 38 that exchanges heat between the cooling water and outside air, a fan 40 for supplying air to the heat exchanger 38, and the like. The heat exchanger 38 of the cooling tower 12 is exposed to the outside air (external environment), and the cooling water and the outside air are directly heat-exchanged in the heat exchanger 38. The cooling tower 12 is accommodated in a housing 41.

Subsequently, the structure of the cooling device 10 described above will be described in more detail.

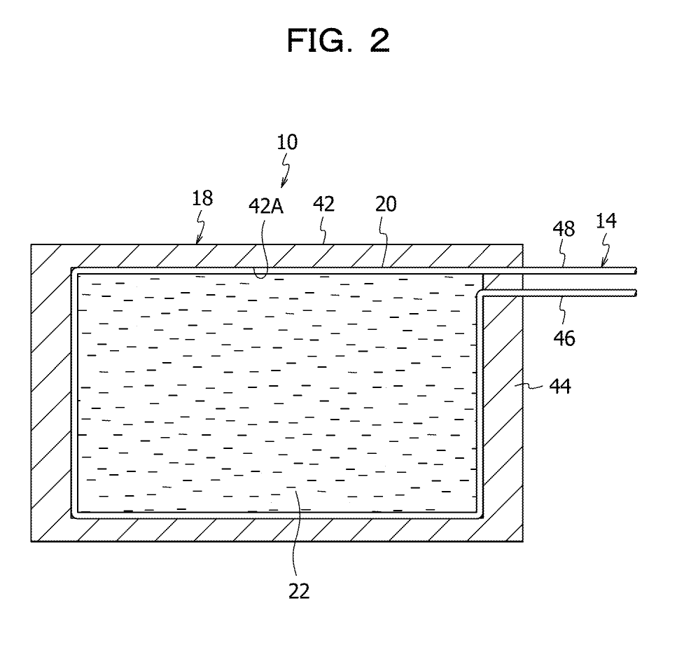

In FIG. 2, the cooling device 10 illustrated in FIG. 1 is illustrated in a plan sectional view. As illustrated in FIG. 2, the cooling pipe 20 of the cooling device 10 corresponds to a portion disposed along a peripheral wall 42 of the immersion tank 18 in the circulation pipe 14. In the example illustrated in FIG. 2, more specifically, the cooling pipe 20 corresponds to a portion from one wall portion 44 of the peripheral wall 42 of the immersion tank 18 to a portion returning to the wall portion 44. The cooling pipe 20 may have a circular cross section, or may have a shape other than the circular cross section.

A pair of connection portions 46 and 48 are formed continuously at the inlet portion and the outlet portion of the cooling pipe 20, respectively. The pair of connection portions 46 and 48 are led out to the outside of the immersion tank 18, and are connected to the supply pipe 34 and the return pipe 36 described above (refer to FIG. 1), respectively.

The cooling pipe 20 is formed in a square frame shape along the peripheral wall 42, and is fixed to an inside surface 42A of the peripheral wall 42. The cooling pipe 20 is disposed inside the immersion tank 18 from the inside surface 42A of the peripheral wall 42 and the entirety thereof is exposed from the peripheral wall 42 to the inside of the immersion tank 18. The cooling pipe 20 is fixed to the peripheral wall 42 in a state of being in contact with the inside surface 42A of the peripheral wall 42, for example. The cooling pipe 20 is disposed at a position in contact with the refrigerant liquid 22 and has a function as a heat exchanger that exchanges heat between the cooling water flowing through the cooling pipe 20 and the refrigerant liquid 22.

In the present embodiment, the portion of the circulation pipe 14 from the one wall portion 44 of the peripheral wall 42 of the immersion tank 18 to the portion returning to the wall portion 44 is referred to as a “cooling pipe” (heat exchange pipe for heat exchange with refrigerant liquid). However, the entirety of the pipe (pipe illustrated in FIG. 2) disposed in the cooling device 10 including the cooling pipe 20 and the pair of connection portions 46 and 48 may be regarded as “cooling pipe”. In addition, in this case, the portion of the “cooling pipe” exposed from the peripheral wall 42 to the inside of the immersion tank 18 may be regarded as “exposed portion” or “heat exchange portion for heat exchange with the refrigerant liquid”.

Next, an operation of the cooling system S including the cooling device 10 will be described.

In the cooling system S of the present embodiment illustrated in FIG. 1, the electronic device 26 is accommodated in the immersion tank 18, and the electronic device 26 is immersed in the refrigerant liquid 22 stored in the immersion tank 18. Heat generated from the electronic device 26 is absorbed by the refrigerant liquid 22, and thus the electronic device 26 is cooled. The refrigerant liquid 22 is stored in the immersion tank 18 without being circulated outside the immersion tank 18. In addition, as the agitating mechanism 24 operates, the refrigerant liquid 22 is agitated inside the immersion tank 18, and the heat generated from the electronic device 26 is efficiently absorbed by the refrigerant liquid 22.

In addition, the circulation pump 16 operates, and the cooling water circulates between the immersion tank 18 and the cooling tower 12 through the circulation pipe 14 including the cooling pipe 20. In the immersion tank 18, the heat exchange is performed between the refrigerant liquid 22 and the cooling water flowing through the cooling pipe 20, and the refrigerant liquid 22 is cooled. Here, as illustrated in FIG. 2, the cooling pipe 20 is exposed from the peripheral wall 42 to the inside of the immersion tank 18. Therefore, for example, as compared with a case where the entirety of the cooling pipe 20 is embedded in the peripheral wall 42, the heat exchange is efficiently performed between the refrigerant liquid 22 and the cooling water flowing through the cooling pipe 20.

The cooling water that is absorbed the heat of the refrigerant liquid 22 while flowing through the cooling pipe 20 is sent to the cooling tower 12 through the return pipe 36 illustrated in FIG. 1, and is cooled in the cooling tower 12. More specifically, in the cooling tower 12, air is supplied to the heat exchanger 38 by the operation of the fan 40, and the cooling water and the outside air are directly heat-exchanged in the heat exchanger 38, and the cooling water is cooled. The cooling water cooled in the cooling tower 12 in this manner is sent to the cooling pipe 20 through the supply pipe 34.

As the cooling water circulates between the immersion tank 18 and the cooling tower 12 through the circulation pipe 14 in this manner, the heat generated in the electronic device 26 is transported to the cooling tower 12, and the electronic device 26 is cooled.

Next, operations and effects of the present embodiment will be described.

As described in detail above, according to the cooling system S of the present embodiment, the cooling device 10 is configured to hold the refrigerant liquid 22 in the immersion tank 18 without being circulated outside the immersion tank 18. Therefore, as compared with a cooling system that circulates a refrigerant liquid between an immersion tank and a heat radiating portion, it is possible to reduce the amount of the refrigerant liquid 22 which is normally considered to be expensive to be used by the amount of the refrigerant liquid 22 held in the immersion tank 18. As a result, it possible to reduce the cost.

In addition, since the refrigerant liquid 22 is held in the immersion tank 18 without being circulated outside the immersion tank 18, leakage of the refrigerant liquid 22 from the cooling system S may be suppressed. Furthermore, since it is not desirable to circulate the refrigerant liquid 22, which is normally considered to have high viscosity, it is not desirable to pump for circulating the refrigerant liquid, so the cost may be reduced. In addition, since the power for operating the pump for circulating the refrigerant liquid may be reduced, power consumption may be saved. Furthermore, a pipe for circulating the refrigerant liquid 22 out of the immersion tank 18 is not desirable, so that the cooling system S may be downsized.

In addition, the cooling tower 12 is used for the cooling system S, instead of a refrigerator or a cold water chiller, the cooling water and the outside air are directly heat-exchanged in the heat exchanger 38 in the cooling tower 12, and the heat of the cooling water is directly released to the outside air. Therefore, power consumption desired for cooling the cooling water may be reduced as compared with a case of using, for example, the refrigerator or the cold water chiller.

In addition, the cooling pipe 20 is exposed from the peripheral wall 42 to the inside of the immersion tank 18. Therefore, since the heat exchange may be efficiently performed between the refrigerant liquid 22 and the cooling water flowing through the cooling pipe 20, it is possible to enhance a cooling capability for the refrigerant liquid 22, and consequently a cooling capability for the electronic device 26.

In particular, the cooling pipe 20 is formed in a frame shape along the peripheral wall 42, and the entirety thereof is exposed from the peripheral wall 42 to the inside of the immersion tank 18. Therefore, since a contact area between the cooling pipe 20 and the refrigerant liquid 22 may be enlarged, the heat exchange may be efficiently performed between the refrigerant liquid 22 and the cooling water flowing through the cooling pipe 20. As a result, it is possible to enhance the cooling capability for the refrigerant liquid 22, and consequently the cooling capability for the electronic device 26.

In addition, the cooling pipe 20 functioning as the heat exchanger that exchanges heat between the refrigerant liquid 22 and the cooling water is integrated with the immersion tank 18. Therefore, since the configuration of the cooling device 10 may be simplified, the cost of the cooling device 10 may be reduced.

Next, modification examples of the present embodiment will be described.

In the above embodiment, although the entirety of the cooling pipe 20 is exposed from the peripheral wall 42 to the inside of the immersion tank 18, a portion of the cooling pipe 20 (for example, a portion in radial direction of cooling pipe 20) may be exposed from the peripheral wall 42 to the inside of the immersion tank 18 and a remaining portion of the cooling pipe 20 may be embedded in the peripheral wall 42. In a case where a portion of the cooling pipe 20 is exposed from the peripheral wall 42 to the inside of the immersion tank 18 in this manner and the remaining portion of the cooling pipe 20 is embedded in the peripheral wall 42, it is desirable that a space between the cooling pipe 20 and the inside surface 42A of the peripheral wall 42 is sealed with, for example, a sealing material or the like.

In addition, in the above embodiment, although the cooling pipe 20 is formed in the frame shape along the peripheral wall 42, the cooling pipe 20 may be formed in a shape other than the frame shape.

In addition, the cooling pipe 20 may be configured as follows, for example. Hereinafter, a first to third modification examples of the cooling pipe 20 will be described.

### FIRST MODIFICATION EXAMPLE

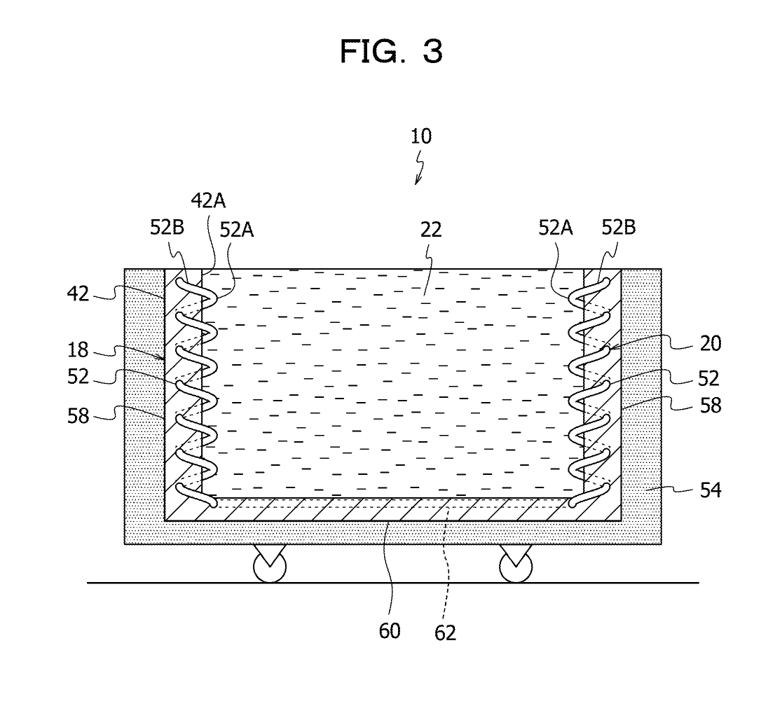

In FIG. 3, a cooling device 10 to which a first modification example of the cooling pipe 20 is applied is illustrated in a side sectional view. In the first modification example illustrated in FIG. 3, the cooling pipe 20 has a plurality of spiral portions 52 forming a spiral with the depth direction of the immersion tank 18 as the axial direction. A portion 52A of the spiral portion 52 is exposed from the peripheral wall 42 to the inside of the immersion tank 18 and a remaining portion 52B of the spiral portion 52 is embedded in the peripheral wall 42. The spiral portion 52 and the spiral portion 52 respectively disposed on the wall portion 58 opposed to each other among the peripheral wall 42 are connected by a connecting portion 62 embedded in the bottom portion 60 of the immersion tank 18.

In this manner, even if the cooling pipe 20 has the spiral portion 52, since the contact area between the cooling pipe 20 and the refrigerant liquid 22 may be enlarged, the heat exchange may be efficiently performed between the refrigerant liquid 22 and the cooling water flowing through the cooling pipe 20. As a result, it is possible to enhance the cooling capability for the refrigerant liquid 22, and consequently the cooling capability for the electronic device 26.

The entirety of the spiral portion 52 may be exposed from the peripheral wall 42 to the inside of the immersion tank 18. In addition, as illustrated in FIG. 3, a heat insulating layer 54 may be disposed outside the immersion tank 18.

### SECOND MODIFICATION EXAMPLE

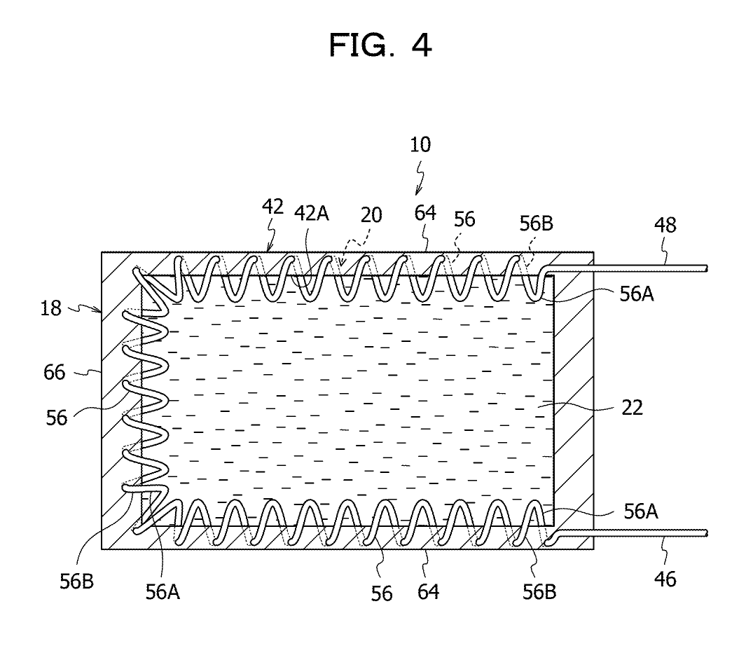

In FIG. 4, a cooling device 10 to which a second modification example of the cooling pipe 20 is applied is illustrated in a plan sectional view. In the second modification example illustrated in FIG. 4, the cooling pipe 20 formed in a frame shape along the peripheral wall 42 has a plurality of spiral portions 56 forming a spiral with the horizontal direction of the immersion tank 18 as the axial direction. The plurality of spiral portions 56 are respectively disposed on wall portions 64 opposed to each other and a wall portion 66 connecting the wall portion 64 and the wall portion 64 among the peripheral wall 42. The plurality of spiral portions 56 are connected in series to each other. A portion 56A of the spiral portion 56 is exposed from the peripheral wall 42 to the inside of the immersion tank 18, and a remaining portion 56B of the spiral portion 56 is embedded in the peripheral wall 42. The entirety of the spiral portion 56 may be exposed from the peripheral wall 42 to the inside of the immersion tank 18.

In this manner, even if the cooling pipe 20 has the spiral portion 56, since the contact area between the cooling pipe 20 and the refrigerant liquid 22 may be enlarged, the heat exchange may be efficiently performed between the refrigerant liquid 22 and the cooling water flowing through the cooling pipe 20. As a result, it is possible to enhance the cooling capability for the refrigerant liquid 22, and consequently the cooling capability for the electronic device 26.

### THIRD MODIFICATION EXAMPLE

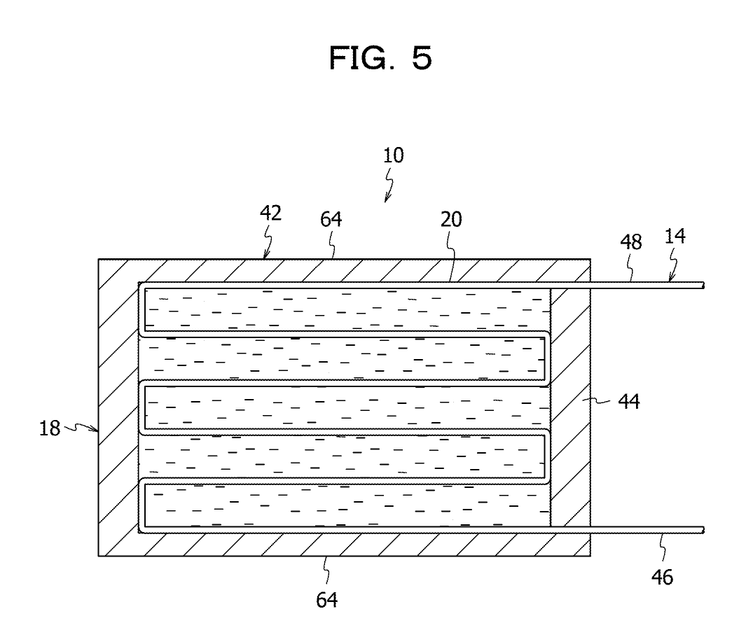

In FIG. 5, a cooling device 10 to which a third modification example of the cooling pipe 20 is applied is illustrated in a plan sectional view. In the third modification example illustrated in FIG. 5, the cooling pipe 20 meanders from one side to the other side of the wall portions 64 opposed to each other among the peripheral wall 42. In the third modification example, the entirety of the meandering cooling pipe 20 is exposed from the peripheral wall 42 to the inside of the immersion tank 18. A portion of the meandering cooling pipe 20 may be exposed from the peripheral wall 42 to the inside of the immersion tank 18 and the other remaining portion (for example, a portion in radial direction of portion along peripheral wall 42) may be embedded in the peripheral wall 42.

In this manner, even if the cooling pipe 20 meanders, since the contact area between the cooling pipe 20 and the refrigerant liquid 22 may be enlarged, the heat exchange may be efficiently performed between the refrigerant liquid 22 and the cooling water flowing through the cooling pipe 20. As a result, it is possible to enhance the cooling capability for the refrigerant liquid 22, and consequently the cooling capability for the electronic device 26.

### OTHER MODIFICATION EXAMPLE

In the above embodiment, the cooling device 10 is applied to the electronic apparatus 30, and the cooling device 10 accommodates the electronic device 26. However, in a case where the cooling device 10 is applied to an apparatus other than the electronic apparatus 30, the cooling device 10 may accommodate an object to be cooled other than the electronic device 26.

In addition, in the above embodiment, the cooling device 10 preferably includes the agitating mechanism 24, but the agitating mechanism 24 may be omitted.

The plurality of modification examples may be appropriately combined.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A cooling device comprising:
an immersion tank that stores a refrigerant liquid; and
a cooling pipe that is disposed on a peripheral wall of the immersion tank, at least a portion of which is exposed from the peripheral wall to an inside of the immersion tank, and through which cooling water flows.

2. The cooling device according to claim 1,
wherein an agitating mechanism that allows the refrigerant liquid to agitate is disposed in the immersion tank.

3. The cooling device according to claim 1,
wherein the cooling pipe is formed in a frame shape along the peripheral wall.

4. The cooling device according to claim 1,
wherein the cooling pipe includes a spiral portion forming a spiral with a depth direction of the immersion tank as an axial direction.

5. The cooling device according to claim 1,
wherein the cooling pipe includes a spiral portion forming a spiral with a horizontal direction of the immersion tank as an axial direction.

6. The cooling device according to claim 1,
wherein the cooling pipe meanders.

7. An electronic apparatus comprising:
an immersion tank that stores a refrigerant liquid;
an electronic device that is accommodated in the immersion tank and is immersed in the refrigerant liquid; and
a cooling pipe that is disposed on a peripheral wall of the immersion tank, at least a portion of which is exposed from the peripheral wall to an inside of the immersion tank, and through which cooling water flows.

8. A cooling system comprising:
an immersion tank that is disposed in a building and stores a refrigerant liquid;
a cooling pipe that is disposed on a peripheral wall of the immersion tank, at least a portion of which is exposed from the peripheral wall to an inside of the immersion tank, and through which cooling water flows; and
a cooling tower that is disposed outside the building, in which the cooling water circulates between the cooling tower and the immersion tank through a circulation pipe including the cooling pipe, and that exchanges heat between the cooling water and outside air.

9. The cooling system according to claim 8,
wherein a circulation pump is disposed in the circulation pipe.
